(19) United States
(12) Patent Application Publication
(10) Pub. No.: US 2025/0125579 A1
(43) Pub. Date: Apr. 17, 2025

(54) ELECTRONIC CIRCUIT AND LASER SCANNER

(71) Applicant: SICK AG, Waldkirch (DE)

(72) Inventor: Rene VOIGT, Waldkirch (DE)

(21) Appl. No.: 18/910,931

(22) Filed: Oct. 9, 2024

(30) Foreign Application Priority Data
Oct. 11, 2023 (DE) 102023127718.9

(51) Int. Cl. H01S 5/042; G01S 7/481

(52) U.S. Cl. CPC H01S 5/042; G01S 7/4813

(57) ABSTRACT

A laser scanner and an electronic circuit for generating laser pulses for a laser scanner, having an input contact for an input voltage,

having a serial connection connected to the input contact, comprising at least one coil and at least one first diode, wherein the first diode is connected in the forward direction for the input voltage, wherein at least one switch element connected to the serial connection is arranged, wherein a switch path is formed by means of the switch element can be applied to the gate of the switch element, wherein at least one anti-parallel circuit of a laser diode and a second diode is connected to the cathode of the first diode and to the switch element at one end, wherein the anti-parallel circuit of the laser diode and the second diode is connected to at least one first capacitor at the other end and the first capacitor is connected to ground at the other end, and wherein an optical laser pulse can be generated at the laser diode by the laser trigger signal at the switch element.

The present invention relates to an electronic circuit for generating laser pulses for a laser scanner and to a laser scanner.

Existing solutions typically provide either a circuit having a high degree of defect tolerance with respect to the classification of laser class 1, eye safety and unwanted laser emission due to a component defect or a more energy efficient circuit, that is a relationship of an input power from the power supply for the power supply of the laser diode. A low energy efficiency is acceptable as a rule for laser diodes having a small power. With more recent sensor applications having very modern high performance laser diodes, a low energy efficiency of the driver circuit can increase the total power consumption of the sensor by approximately 30-40%. On the other hand, know solutions for more energy efficient laser driver circuits are considerably more susceptible to component failures that result in an unwanted laser light emission and thus most probably result in an infringement of the limit values of laser class 1. To avoid such a scenario, an increased demand on suitable safety detection mechanisms is required, which results in an increased system complexity and higher production costs.

The invention provides a solution for an energy efficient laser driver circuit having a high degree of defect tolerance to overcome this design compromise.

Fundamental concepts of conventional laser circuit drivers will be described in the following:

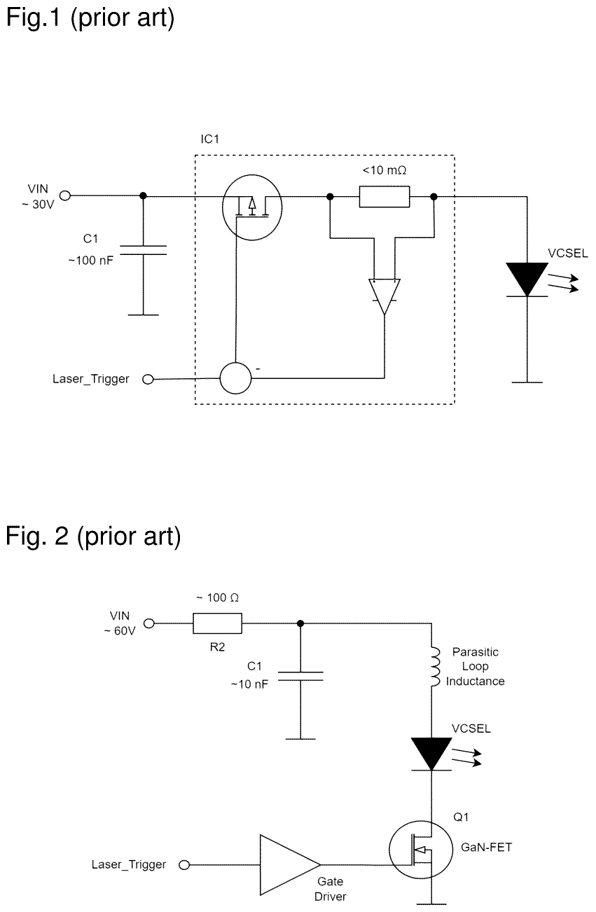

FIG. 1 shows a high-side driver solution in accordance with the prior art. In this concept, a high-side switch element is used to conduct a current through the laser diode. It can here be an integrated or a discrete solution. A short circuit of the driving switch element directly results in an unwanted laser light emission. The pulse width of the trigger signal also has a direct effect on the emission time. Comprehensive detection mechanisms within the driver are required to ensure the laser class 1.

FIG. 2 shows a resonant capacitive discharge laser driver in accordance with the prior art. A widespread and frequently used laser driver circuit is based on a resonant design comprising a capacitor, a laser diode, and a low-side switch element. Field effect transistors are typically used. The capacitor is charged and as a rule sores the energy for a single laser pulse. The switch element is closed and the charge of the capacitor is conducted through the laser diode to emit laser light. The loop inductance of the current loop forms a resonant circuit with the capacitor and thus defines the pulse shape.

A simple and defect tolerant possibility of charging the capacitor is the use of a resistor between the input supply and the capacitor. The efficiency during charging is always at approximately 50% since the capacitor is almost completely discharged on every shot. This concept is still susceptible to a short circuit failure of the switch element. Although the current flow through the resistor is limited, an unwanted laser emission is nevertheless possible due to a component failure. In practice, a plurality of different concepts are used to precharge and to arrange these components.

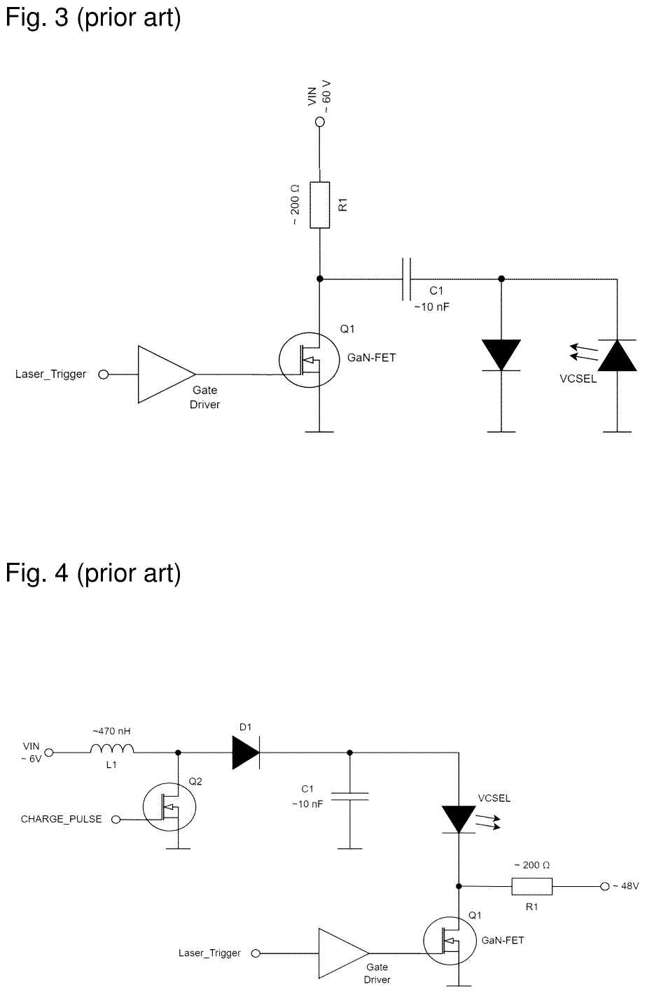

FIG. 3 shows an improved low-side driver design based on a single transistor avalanche plus design in accordance with the prior art. The capacitor is precharged on the cathode side of the laser diode instead of the anode side to prevent an unwanted laser light emission in the event of a short circuit of the switch element.

An atypical component failure within this concept can result in an unwanted laser emission. The only possibility of infringing the limit values of laser class 1 is an incorrect input supply voltage and an incorrect laser trigger signal, for example an incorrect pulse width and/or an incorrect repeat time. The additional diode in this circuit is optional. The use of this diode serves to prevent unwanted bell effects and has no general function with respect to precharge or laser light emission.

FIG. 4 shows a resonant laser driver having a high-side boost circuit in accordance with the prior art.

A further concept is the use of a boost converter topology as the charge circuit. There are also an inductor, a diode, and an additional transistor. The additional transistor is closed for a defined time for the precharge. The time defines the voltage to which the capacitor is charged. After the opening of the transistor, the energy stored in the inductor is amplified within the capacitor by the added diode. An additional voltage is required at the cathode of the laser diode to prevent a current flowing through the laser diode at this moment to charge the drain source capacitance of the transistor. The input voltage is adapted such that it is below the threshold value to prevent a laser light emission in the event of a short circuit of the switch element. This concept is, however, very susceptible to an inaccurate timing of the charge signal and in particular to component tolerances. It must therefore be assumed that fast-response safety detection mechanisms are required for the application of laser class 1.

A further development of this solutions is represented by the patent family of the patent U.S. Pat. No. 9,368,936 that manages without said additional transistor and achieves an almost constant doubling of the input voltage with a high efficiency and in so doing has no particular susceptibility with respect to timing and component tolerances. It must, however, be named as a disadvantage that a simple component defect of the switch element can already result in an unwanted laser emission and in an infringement of eye safety in this solution without any additional detection mechanisms. Other concepts are also described in the patents U.S. Pat. No. 11,075,502 B2, U.S. Pat. No. 11,631,961 B2, and U.S. Pat. No. 10,673,204 B2 that describe further possible circuits and solutions for driver circuits for laser diodes in a pulsed laser light application.

As a rule, existing solutions use a concept having a high degree of defect tolerance with respect to eye safety and unwanted laser emission due to a component defect. As a rule, existing solutions also have low energy efficiency with respect to the input power from the power supply for the electrical power supply of the laser diode. Other solutions use circuits having a higher energy efficiency, but also a high susceptibility to component failures so that there is an increased demand on safety detection mechanisms. The individual disadvantages of the currently known solutions have been explained above. A high input supply voltage, for example greater than 60 volts, is furthermore required for most high performance applications so that additional measures are required to satisfy the electrical safety standards within the overall system.

US 2021/0333362 A1 likewise discloses a light emission device. The light emission device comprises at least two laser emission circuits, with each of the laser emission circuits comprising a power supply, a laser emitter, an energy storage circuit, and a control circuit; in each of the laser emission circuits, the control circuit is configured such that it switches on the energy storage circuit and the power supply in the laser emission circuit in a first time period so that the power supply can store energy in the energy storage circuit; the control circuit is furthermore configured such that it switches on the laser emitter and the energy storage circuit in the laser emission circuit in a second time period so that the energy storage circuit supplies the laser emitted with power so that the laser emitter transmits a light pulse signal; and two or more laser emission circuit circuits share the power supply.

It Is an object of the invention to provide an improved driver circuit having a high degree of defect tolerance for laser diodes in a pulsed laser light application having a pulse width of a few nanoseconds and a high, unchanging pulse energy at high peak currents.

The object is satisfied by an electronic circuit for generating laser pulses for a laser scanner having an input contact for an input voltage, having a serial connection connected to the input contact and comprising at least one coil and at least one first diode, wherein the first diode is connected in the forward direction for the input voltage, wherein at least one switch element connected to the serial connection is arranged, wherein a switch path is formed by means of the switch element; wherein a laser trigger signal can be applied to the gate of the switch element, wherein at least one anti-parallel circuit of a laser diode and a second diode is connected to the cathode of the first diode and to the switch element at one end, wherein the anti-parallel circuit of the laser diode and the second diode is connected to at least one first capacitor at the other end and the first capacitor is connected to ground at the other end, and wherein an optical laser pulse can be generated at the laser diode by the laser trigger signal at the switch element.

After the start and the application of a voltage to the input contact, the first capacitor is charged via the coil, the first diode, and the second diode by an input voltage at the input contact.

The first capacitor is a single capacitor or a series of capacitors to cache the energy required for a single laser shot.

The switch element is a switch element, for example, having a very fast switch time that is able to carry a high peak current during the laser pulse and to withstand a high charge voltage. The switch element is controlled by the external laser trigger signal or control signal at the control signal input. A low-side driver is preferably provided to control the gate of the switch element used. The switch element only conducts for an extremely limited time when the external laser trigger signal is activated.

The first capacitor is fully discharged by the laser diode and the switch element and a first lower laser pulse is generated during the first pulse of the laser trigger signal, starting at a first point in time. At this moment, the voltage level of the laser diode cathode (corresponds to the drain of the switch element) is the same as the ground reference, which results in a voltage drop from the first capacitor to the switch element equal to the input voltage. A current begins to flow through the coil and the first diode.

Once the switch element has closed, the current through the coil and the first diode further increases and charges the first capacitor up to the voltage of the second diode until the voltage level at the laser diode cathode reaches the level of the input voltage at a second point in time and is now at the same voltage level as the input voltage. The current through the coil falls from now onward until it has again reached 0 amperes at a third point in time. The first capacitor is in the meantime still charged to a voltage level that almost corresponds to twice the input voltage.

After the third point in time, a negative current through the coil through the first diode is prevented so that the first capacitor is not discharged through the laser diode and the coil. Under real conditions, only a slight oscillation remains that does not, however, result in an unwanted illumination of the laser diode. The first capacitor stores the energy for the next laser pulse at a charge voltage of almost twice the input voltage until the laser trigger signal again triggers the circuit at a fourth point in time.

There is a fundamental difference, in particular in comparison with the patent application US 2021/0333362, in the idea how the switch element is used in accordance with the invention. With a resonant laser driver having a high-side boost circuit and normal boost converter circuits, the switch element is closed for as long as necessary to increase the current through the inductor and the switch element to increase the magnetic field within the inductor to a specific value to achieve a charge voltage that is a multiple of the input voltage. The stored charge at the first capacitor or the charge voltage can be controlled by changing the tie in which the switch element is closed.

The switch element is only closed for a limited time in this invention, in particular an extremely limited time, namely a few nanoseconds, to release the laser light pulse. No appreciable current can be built up by the inductor and the switch element during this time. However, the very short time in which the switch element is closed is sufficient that the voltage level of the laser diode cathode amount to almost 0 volts and the previously described charge current is started. As long as the switch element is not closed for very much longer, the voltage at the first capacitor after the charging amounts to almost twice the input voltage, independently of when the switch element was closed. On the one hand, this means that the possibility of directly controlling the charge voltage is lost with the closing time of the switch element. On the other hand, it is not possible to generate a voltage that is greater than twice the input voltage and the maximum energy per pulse is thus absolutely predictable. No additional safety mechanism, e.g. high speed voltage measurement, is necessary. And the energy per pulse can still be controlled by changing the input supply voltage that can be measured by a relatively slow voltage measurement.

To further improve the susceptibility with respect to an incorrect pulse width of the laser trigger signal, the coil or the inductor can be used in which the peak charge current through the coil is close to the saturation current of the inductor type. Even if the pulse width of the laser trigger signal is too large, the coil or the inductor is not able to store more magnetic energy and thus to prevent an overcharging of the first capacitor. In addition, the current through the coil increases quickly and a power switch that is simple to implement can recognize such a defect situation.

The laser diode is, for example, a 5J VCSEL laser diode or a multichannel edge emitter.

The most important advantages of this invention are:

A high charge efficiency of up to 97% in comparison with the typically used RC charge circuit at 50%. The total efficiency, namely the electrical input power to the optical output power, depends on said charge efficiency, the power conversion efficiency of the laser diode, and the discharge efficiency, primarily defined by the losses within the switch element used.

No harmful laser emission takes place on typical component failures, e.g. short circuit of the switch element, and thus no safety detection mechanisms are required within the laser driver circuit. The integrity of the incoming voltage supply and of the laser trigger signal at the corresponding modules has to be ensured where they are produced. A hazardous laser light emission can only occur when an input signal is not correct, that is an incorrect supply voltage or an incorrect laser trigger signal is present.

This is a robust system against insufficient accuracy of the pulse width of the laser trigger signal.

There is no uncritical minimum pulse width and no uncritical shutdown behavior of the switch element.

Only a relatively low input voltage is required in comparison with the required peak voltage for the generation of laser shots. The high voltage is restricted to the laser drive circuit so that the demands of the electrical safety standards can be satisfied more easily.

Stable, repeatable pulse shapes having unchanging pulse energy are produced.

In a further development of the invention, at least one second capacitor connected in parallel is arranged connected to the input contact.

The second capacitor is a capacitor or there are, for example, a plurality of bulk capacitors having a greater capacitance than the first capacitor to enable a sufficient stabilization of the input voltage at the input contact.

In a further development of the invention, the switch element is in particular a switch transistor, in particular a field effect transistor, very particularly a gallium nitride field effect transistor.

Unlike the current controlled bipolar transistors, field effect transistors are voltage controlled circuit elements. The control takes place via the gate source voltage that serves for the regulation of the channel cross-section or the charge carrier density, i.e. of the semiconductor resistor to thus switch or control the power of an electrical current.

Field effect transistors are particularly suited for the switching of high currents. Gallium nitride field effect transistors are particularly suited for the switching of high currents.

In a further development of the invention, the laser trigger signal is produced by a low-side FET driver. The low-side FET driver is an integrated electronic circuit that controls the power switch, that is the switch element.

A transistor driver or the low-side FET driver is a circuit that provides the required voltage to switch a transistor on or off in the required time. It is here typically an amplifier having an additional level converter. It is thereby possible to switch large loads such as field effect transistors with a logic output that is typically operated at 5 or 3.3 V. This driver can operate in an analog or digital manner.

The first capacitor is fully discharged by the laser diode and the switch element and a first lower laser pulse is generated during the first pulse of the laser trigger signal, starting at a first point in time. At this moment, the voltage level of the laser diode cathode is the same as the ground reference, which results in a voltage drop from the second capacitor to the switch element equal to the input voltage.

If the pulse width of the laser trigger signal is selected to be longer than the calculated laser pulse width, a complete discharge of the first capacitor is ensured.

In a further development of the invention, the capacitance of the second capacitor is at least 500 times greater and in particular 1000 times greater than the capacitance of the first capacitor to enable a sufficient stabilization of the input voltage at the input contact.

In a further development of the invention, the switch element is closed by the laser trigger signal for only 5 to 50 nanoseconds, in particular 15 to 20 nanoseconds, to release a laser pulse at the laser diode.

The further development relates to a driver circuit for laser diodes in a pulsed laser light application having a pulse width of a few nanoseconds, in particular 5 to 30 ns, and high pulse energy, for example a few uJ per laser shot having high peak currents. Greater than 100 amperes are used, for example.

The switch element is only closed for an extremely limited time, namely a few nanoseconds, to release the laser light pulse. No appreciable current can be built up by the inductor and the switch element during this time. However, the very short time in which the switch element is closed is sufficient that the voltage level of the laser diode cathode amounts to almost 0 V and the previously described charge current is started. As long as the switch element is not closed for very much longer, the voltage at the capacitor after the charging amounts to almost twice the input voltage, independently of when the switch element was closed. On the one hand, this means that the possibility of directly controlling the charge voltage is lost with the closing time of the switch element. On the other hand, it is not possible to generate a voltage that is greater than twice the input voltage and the maximum energy per pulse is thus absolutely predictable. No additional safety mechanism, e.g. high speed voltage measurement, is necessary. And the energy per pulse can still be controlled by changing the input supply voltage that can be measured by a relatively slow voltage measurement.

In a further development of the invention, the energy per laser pulse is set by a control of the input supply voltage.

The energy per laser pulse can thus be set or controlled or regulated easily by means of the input supply voltage used.

In a further development of the invention, the energy per laser pulse is set by a change of the pulse width of the laser trigger signal.

In a further development of the invention, the first capacitor, the laser diode, and the switch element, form a resonant discharge laser driver.

This further development uses the principle of the resonant capacitive discharge laser driver and comprises a capacitor, a laser diode, and a switch element. Unlike the conventional solution, the charge circuit is, however, connected to the cathode side of the laser driver while the capacitor is still connected to the anode. An antiparallel diode is added to enable a current flow for the charging. The most critical failure of a short circuited switch element is overcome by this change.

In a further development of the invention, the coil, the first diode, and the switch element form a boost converter circuit, wherein the switch element is only closed for a limited time so that a voltage is produced due to the circuit that is only in dependence on the input voltage, is thus deterministic, and practically corresponds to twice the input voltage.

To overcome the comparably low efficiency of 505 with a typically used charge resistance, a circuit is used having a common boost converter topology comprising an inductance, a diode, and a transistor. The high speed switch element of the oscillating drive circuit is used, with this only being closed for a limited time, in particular for an extremely limited time, so that due to switching a voltage is produced that is only in dependence on the input voltage, is thus deterministic, and practically corresponds to twice the input voltage.

In accordance with the further development, the switch element is closed by the laser trigger signal for, for example, only 5 to 50 nanoseconds, in particular 15 to 20 nanoseconds, to release a laser pulse at the laser diode.

In a further development of the invention, further anti-parallel circuits of laser diodes and diodes are connected in parallel with the antiparallel circuit of the laser diode and of the second diode, with said further antiparallel circuits each being connected to at least one further capacitor and being connected to ground at the other end, wherein an optical laser pulse can be generated simultaneously at all the laser diodes by the laser trigger signal of the switch element.

In a further development of the invention, the laser diodes are arranged in a common housing or on a common substrate.

The object is further satisfied by a laser scanner having an electronic circuit as described herein. A laser scanner has at least one transmission element and having at least one reception element and a control and evaluation unit for evaluating the time of flight of light beams from the transmission element via an object to the reception element. The transmission element has the laser diode.

In a further development of the invention, the laser scanner has least one transmission element and at least one reception element and a control and evaluation unit for evaluating the time of flight of light beams from the transmission element via an object to the reception element. In this respect, a plurality of transmission elements and a plurality of reception elements are arranged in a common housing, wherein the light beams are transmitted and/or received in different angular directions in fan shape, wherein the spacings of the transmitted light beams of the transmission elements increase as the distance from the laser scanner increases and/or the spacings of the received light beams of the reception elements decrease as the distance from the laser scanner decreases. The transmission elements and reception elements are arranged in a row, for example. An angle deflection can take place via an optics.

A preferred application is the use of the electronic circuit in a solid state flash LIDAR sensor of laser class 1.

In accordance with the further development, the light beams are transmitted or received in fan-like form in different angular directions, whereby a monitored zone can be simply examined as to whether objects are present in the monitored zone or not and at which point, i.e. at which distance, the objects are present. The objects can furthermore be measured or a surrounding contour and its change can be detected. The monitored zone is monitored within a fan-like plane by the fan-like transmission of the light beams or by the fan-like reception. The laser scanner can be produced with high angular precision since the transmission elements and reception elements are firmly fixed and the light beams enter into the monitored zone directly without moving parts. It is thereby ensured that every laser scanner observes a specific required minimum angular precision.

The laser scanner therefore has a simple and inexpensive design. Since the laser scanner manages without any mechanically moving parts, it has no mechanical wear and has a long service life. A required duration of use of, for example, approximately 20 years can be satisfied with the laser scanner in accordance with the invention, for example.

Since the laser scanner manages without any moving parts that can be exposed to accelerations on a use in vehicles, for example, the laser scanner in accordance with the invention is less sensitive to vibration and shock loads and can therefore be used without problem in mechanically moved objects such as vehicles, in particular forklift trucks. Since the laser scanner manages without any movable parts, the laser scanner can also have a very compact design.

In a further development of the invention, the laser scanner has least one transmission element and at least one reception element and a control and evaluation unit for evaluating the time of flight of light beams from the transmission element via an object to the reception element. In this respect, a deflection unit is provided to deflect the transmitted light beams of the transmission element and/or to deflect the received light beams for the reception element. The deflection element can, for example, be a rotating mirror or an oscillating mirror.

Due to the deflection unit, only a single transmission element and/or a single reception element has to be provided.

In a further development of the invention, the laser scanner is a multiplane laser scanner, wherein the multiplane laser scanner is configured to form a plurality of scan planes. The plurality of scan planes can, for example, be arranged in fan shape. However, provision can also be made to form a plurality of parallel scan planes.

The invention will also be explained in the following with respect to further advantages and features with reference to the enclosed drawing and embodiments. The Figures of the drawing show in:

FIG. 1 a high-side driver solution in accordance with the prior art;

FIG. 2 a resonant capacitive discharge laser driver in accordance with the prior art;

FIG. 3 an improved low-side driver design based on a single transistor avalanche plus design in accordance with the prior art;

FIG. 4 a resonant laser driver having a high-side boost circuit in accordance with the prior art;

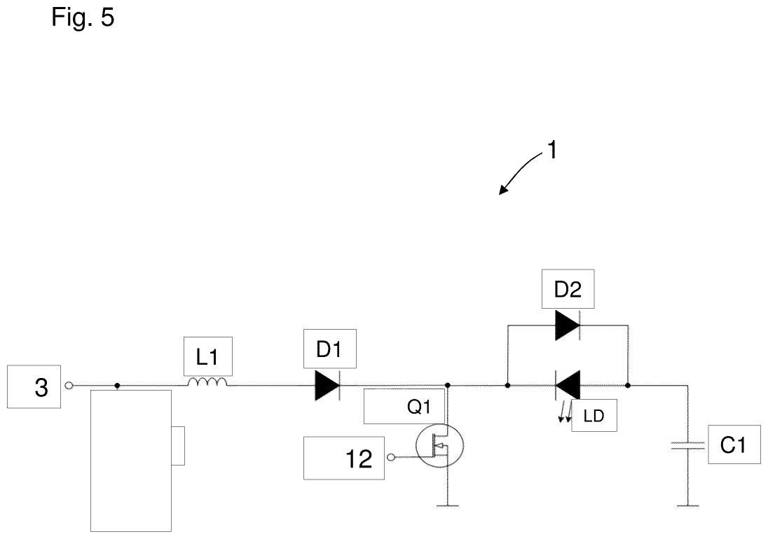

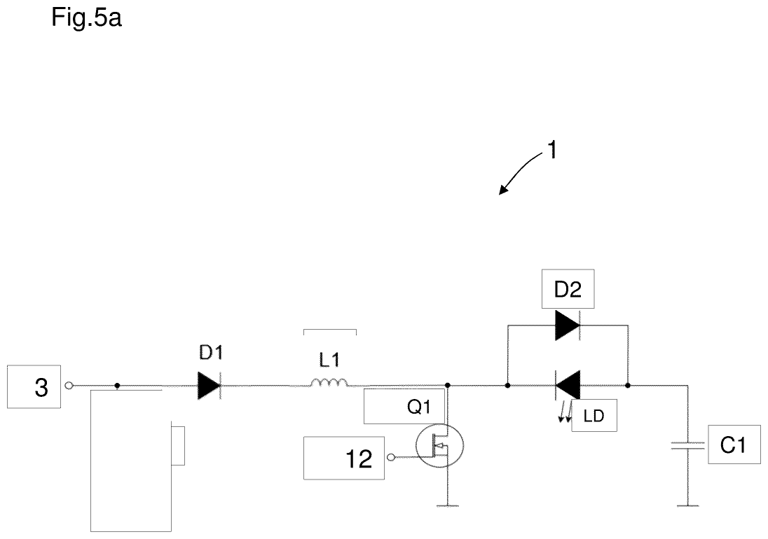

FIG. 5 an electronic circuit to produce laser pulses for a laser scanner;

FIG. 5a an electronic circuit to produce laser pulses for a laser scanner;

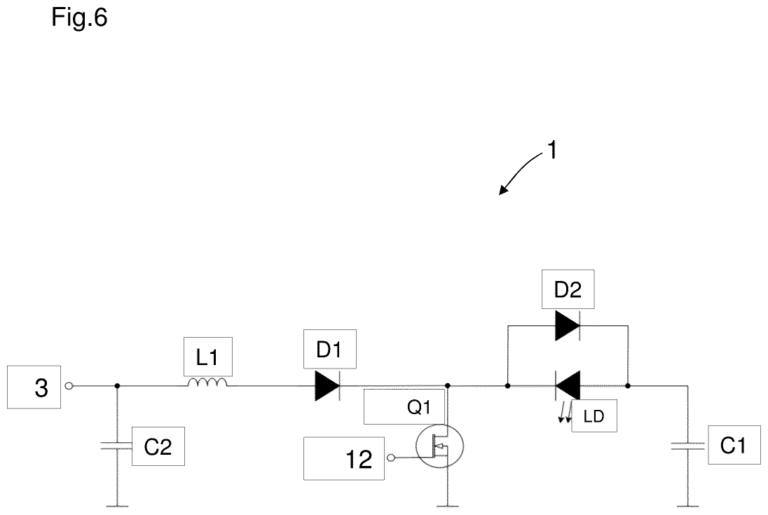

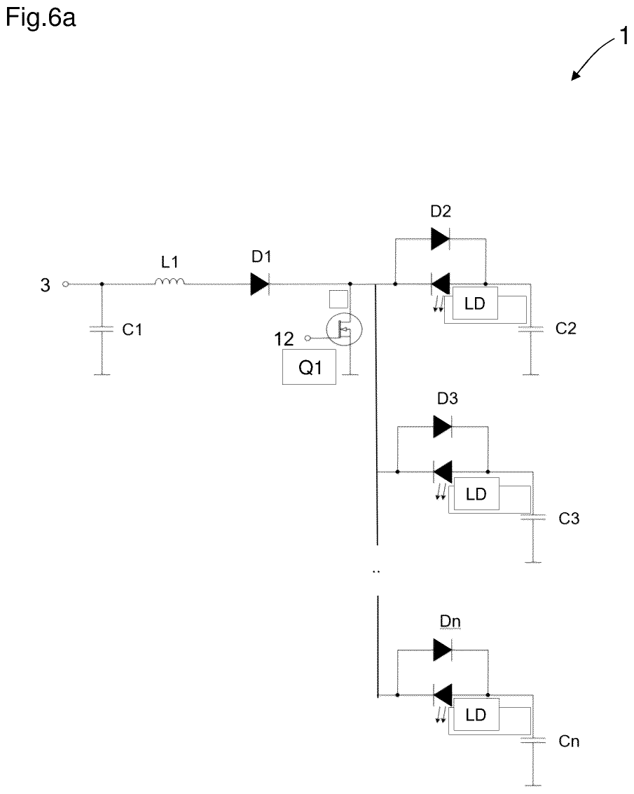

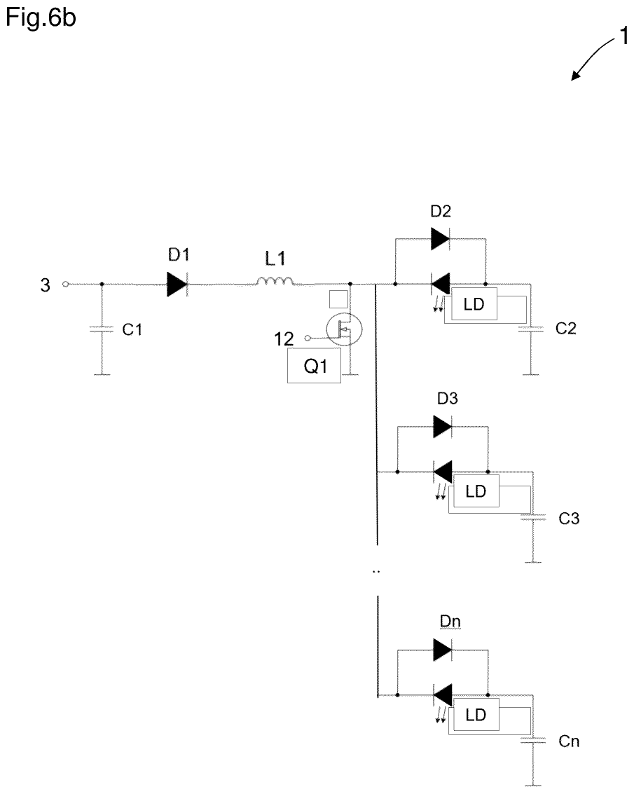

FIG. 6 an electronic circuit to produce laser pulses for a laser scanner;

FIG. 6a an electronic circuit to produce laser pulses for a laser scanner;

FIG. 6b an electronic circuit to produce laser pulses for a laser scanner;

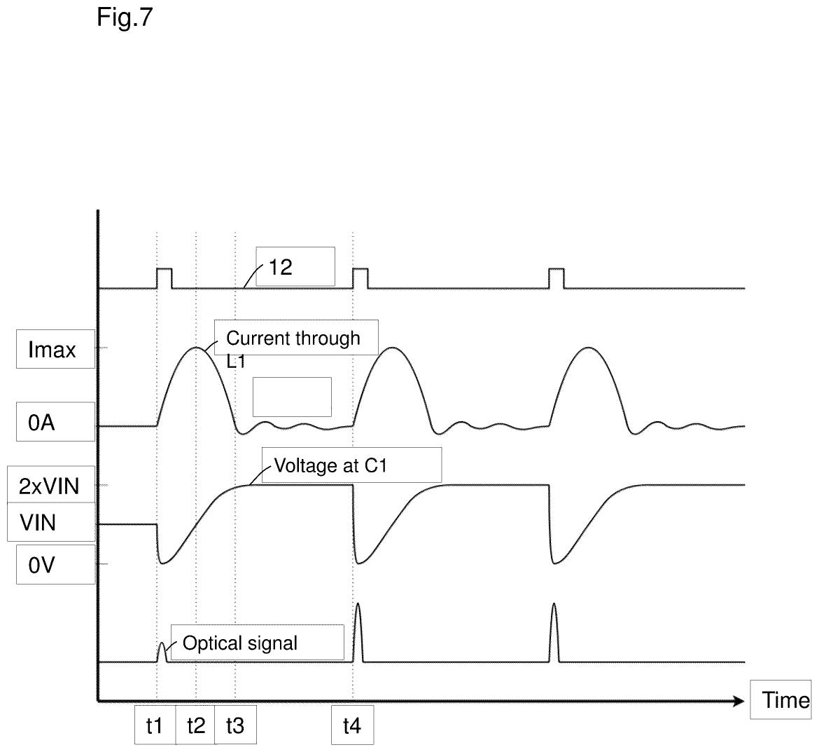

FIG. 7 a diagram of the signals and voltages and currents that occur; and

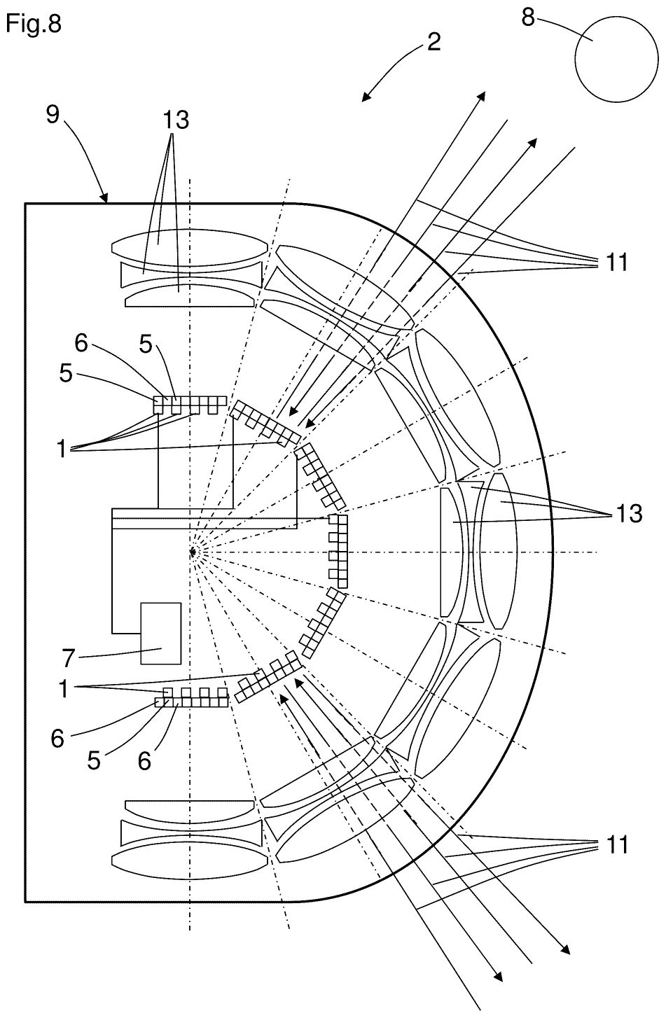

FIG. 8: a laser scanner.

In the following Figures, identical parts are provided with identical reference numerals.

FIG. 5 shows an electronic circuit 1 for generating laser pulses for a laser scanner having an input contact 3 for an input voltage, having a serial connection connected to the input contact and comprising at least one coil L1 and at least one first diode D1, wherein the first diode D1 is connected in the forward direction for the input voltage, wherein at least one switch element Q1 connected to the serial connection is arranged, wherein a switch path is formed by means of the switch element Q1, wherein a laser trigger signal 12 can be applied to the gate of the switch element Q1, wherein at least one anti-parallel circuit of a laser diode LD and a second diode D2 is connected to the cathode of the first diode D1 and to the switch element Q1 at one end, wherein the anti-parallel circuit of the laser diode LD and the second diode D2 is connected to at least one first capacitor C1 at the other end and the first capacitor C1 is connected to ground at the other end, and wherein an optical laser pulse can be generated at the laser diode LD by the laser trigger signal 12 at the switch element Q1.

FIG. 5 shows the electronic circuit 1 having the input contact 3 for the input voltage, having at least the coil L1 connected to the input contact, having at least the first diode D1 connected in series to the coil L1, wherein the first diode D1 is connected in the forward direction for the input voltage, and wherein at least the switch element Q1 connected to the cathode of the first diode D1 is arranged.

In accordance with FIG. 5a, however, the diode D1 can also be connected to the diode D1 and the coil L1 can be connected in series to the diode D1 so that the coil L1 and the diode D1 form a serial connection.

In accordance with FIG. 6, for example, at least one second capacitor C2 connected in parallel is arranged connected to the input contact 3.

After the start and the application of a voltage to the input contact, 3 the second capacitor C2 and the first capacitor C1 are charged via the coil L1, the first diode, D1 and the second diode D2 by an input voltage at the input contact 3. The first capacitor C1 is a single capacitor or a series of capacitors to cache the energy required for a single laser shot. The second capacitor C2 is a capacitor or there are, for example, a plurality of bulk capacitors having a greater capacitance than the first capacitor C1.

The switch element Q1 is a switch element Q1, for example, having a very fast switch time that is able to carry a high peak current during the laser pulse and to withstand a high charge voltage. The switch element Q1 is controlled by the external laser trigger signal 12 or control signal at the control signal input 4. A low-side driver is preferably provided to control the gate of the switch element Q1 used. The switch element Q1 only conducts for an extremely limited time when the external laser trigger signal 12 is activated at a positive level.

FIG. 6a shows the electronic circuit 1 having the input contact 3 for the input voltage, having at least the coil L1 connected to the input contact, having at least the first diode D1 connected in series to the coil L1, wherein the first diode D1 is connected in the forward direction for the input voltage, and wherein at least the switch element Q1 connected to the cathode of the first diode D1 is arranged.

In accordance with FIG. 6b, however, the diode D1 can also be connected to the input contact 3 and the coil L1 can be connected in series to the diode D1 so that the coil L1 and the diode D1 form a serial connection.

In accordance with FIGS. 6a and 6b, further laser diodes LD are respectively arranged in parallel. The laser diodes LD each have an antiparallel diode D2, D3, or Dn. A respective capacitor C2, C3, r Cn is connected in series to the respective laser diode LD and is connected to ground at the other end.

FIG. 7 shows a diagram of the signals and voltages and currents that occur. The diagram of FIG. 6 shows the signal of the laser trigger signal 12, the current through the coil L1, the voltage at the first capacitor C1, and the optical signal at the laser diode LD. Relevant points in time t1, t2, t3, and t4 are in particular shown. The input voltage is marked by VIN. A maximum current through the coil L1 is marked by Imax.

The first capacitor C1 is fully discharged by the laser diode LD and the switch element Q1 and a first lower laser pulse is generated during the first pulse of the laser trigger signal 12, starting at a first point in time t1 in accordance with FIG. 6. At this moment, the voltage level of the laser diode cathode (corresponds to the drain of the switch element Q1) is the same as the ground reference, which results in a voltage drop from the second capacitor C2 to the switch element Q1 equal to the input voltage. A current begins to flow through the coil L1 and the first diode D1.

Once the switch element Q1 has been closed, the current through the coil L1 and the first diode D1 further increases and charges the first capacitor C1 up to the voltage of the second diode D2 until the voltage level at the laser diode cathode reaches the level of the input voltage at a second point in time t2 and is now at the same voltage level as the second capacitor C2. The current through the coil L1 falls from now onward until it has again reached 0 amperes at a third point in time t3. The first capacitor C1 is in the meantime still charged to a voltage level that almost corresponds to twice the input voltage.

After the third point in time t3, a negative current through the coil L1 through the first diode D1 is prevented so that the first capacitor C1 is not discharged through the laser diode LD and the coil L1. Under real conditions, only a slight oscillation remains that does not result in an unwanted illumination of the laser diode LD. The first capacitor C1 stores the energy for the next laser pulse at a charge voltage of almost twice the input voltage until the laser trigger signal 12 again triggers the circuit at a fourth point in time t4.

The switch element Q1 is only closed for a limited time, in particular an extremely limited time, namely a few nanoseconds, to release the laser light pulse. No appreciable current can be built up by the coil L1 and the switch element Q1 during this time. However, the very short time in which the switch element Q1 is closed is sufficient that the voltage level of the laser diode cathode amounts to almost 0 volts and the previously described charge current is started. As long as the switch element Q1 is not closed for very much longer, the voltage at the first capacitor C1 after the charging amounts to almost twice the input voltage, independently of when the switch element Q1 was closed. On the one hand, this means that the possibility of directly controlling the charge voltage is lost with the closing time of the switch element Q1. On the other hand, it is not possible to generate a voltage that is greater than twice the input voltage and the maximum energy per pulse is thus absolutely predictable. No additional safety mechanism, e.g. high speed voltage measurement, is necessary. And the energy per pulse can still be controlled by changing the input supply voltage that can be measured by a relatively slow voltage measurement.

To further improve the susceptibility with respect to an incorrect pulse width of the laser trigger signal 12, the coil L1 or the inductor can be used in which the peak charge current through the coil L1 is close to the saturation current of the inductor type. Even if the pulse width of the laser trigger signal 12 is too large, the coil L1 or the inductor is not able to store more magnetic energy and thus to prevent an overcharging of the first capacitor C1. In addition, the current through the coil L1 increases quickly and a power switch that is simple to implement can recognize such a defect situation.

The laser diode LD is, for example, a 5J VCSEL laser diode or a multichannel edge emitter.

The switch element Q1 is preferably in particular a switch transistor, in particular a field effect transistor FET-Q1, very particularly a gallium nitride field effect transistor GaN-Q1.

The laser trigger signal 12 is preferably generated by a low-side FET driver. The low-side FET driver is an integrated electronic circuit that controls the power switch, that is the switch element Q1.

A transistor driver or the low-side FET driver is a circuit that provides the required voltage to switch the switch element Q1 on or off in the required time. It is here typically an amplifier having an additional level converter. It is thereby possible to switch large loads such as field effect transistors FET-Q1 with a logic output that is typically operated at 5 or 3.3 V. This driver can operate in an analog or digital manner.

The first capacitor C1 is fully discharged by the laser diode LD and the switch element Q1 and a first lower laser pulse is generated during the first pulse of the laser trigger signal 12, starting at a first point in time t1. At this moment, the voltage level of the laser diode cathode is the same as the ground reference, which results in a voltage drop from the second capacitor C2 to the switch element Q1 equal to the input voltage. If the pulse width of the laser trigger signal 12 is selected to be longer than the calculated laser pulse width, a complete discharge of the first capacitor C1 is ensured.

The capacitance of the second capacitor C2 is preferably at least 500 times greater and in particular 1000 times greater than the capacitance of the first capacitor C1.

The switch element Q1 is preferably closed by the laser trigger signal 12 for only 5 to 30 nanoseconds, in particular 15 to 20 nanoseconds, to release a laser pulse at the laser diode LD.

The further development relates to a driver circuit for laser diodes LD in a pulsed laser light application having a pulse width of a few nanoseconds, in particular 5 to 20 ns, and high pulse energy, for example a few uJ per laser shot having high peak currents. Greater than 100 amperes are used, for example.

Preferably, the energy per laser pulse is set by a control of the input supply voltage.

The energy per laser pulse can thus be set or controlled or regulated easily by means of the input supply voltage used.

The first capacitor C1, the laser diode LD, and the switch element Q1 preferably form a resonant discharge laser driver.

Unlike the conventional solution, the charge circuit is, however, connected to the cathode side of the laser driver while the capacitor is still connected to the anode. An antiparallel second diode D2 is added to enable a current flow for the charging. The most critical failure of a short circuited switch element is overcome by this change.

The coil L1, the first diode D1, and the switch element Q1 preferably form a boost converter circuit.

To overcome the comparably low efficiency of 50% with a typically used charge resistor, a circuit is used having a common boost converter topology comprising the coil L1, a first diode, D1 and the switch element Q1. The high speed switch element of the oscillating drive circuit is used, with this only being closed for a limited time, in particular for an extremely limited time, so that due to switching a voltage is produced that due to the circuit is only in dependence on the input voltage, is thus deterministic, and practically corresponds to twice the input voltage.

Exemplary specific values for the components are:
C2=2×4.7 uF (˜10 uF)
L1=6.8 H
D1=NEXPERIA PMEG3010 (Schottky diode having a low VF)
Q1=EPC EPC2088 (GaN enhancement mode power transistor)
D2=NEXPERIA PMEG3010 (Schottky diode having a low VF)
LD (laser diode)=AMS TORONTO (800W 940 nm 5J-VCSEL)
C1=3×3.9 nF ceramic capacitors (11,7 nF)
Input voltage=25−34 V.
Gate driver=TI LMG1020

FIG. 8 shows a laser scanner 2 having electronic circuits 1. The laser scanner 2 has at least one transmission element 5 and at least one reception element 6 and a control and evaluation unit 7 for evaluating the time of flight of light beams from the transmission element 5 via an object 8 to the reception element 6. The transmission element 5 has the laser diode LD. Optional lenses 13 are arranged in front of the transmission elements 5 and the reception elements 6. For greater clarity, not all the signal connections to the electronic circuits 1 are shown.

In accordance with FIG. 8, a plurality of transmission elements 5 and a plurality of reception elements 6 are here arranged in a common housing 9, wherein the light beams 11 are transmitted and/or received in different angular directions in fan shape, wherein the spacings of the transmitted light beams of the transmission elements 5 increase as the distance from the laser scanner 2 increases and/or the spacings of the received light beams of the reception elements 6 decrease as the distance from the laser scanner 2 decreases. The transmission elements 5 and the reception elements 6 are arranged in a row, for example. An angle deflection can take place via an optics. The transmission elements 5 and the reception elements 6 can, however, also be arranged in circular segment shape.

A preferred application is the use of the electronic circuit 1 in a LIDAR sensor of laser class 1.

In accordance with the further development, the light beams 11 are transmitted or received in fan-like form 11 in different angular directions, whereby a monitored zone can be simply examined as to whether objects 8 are present in the monitored zone or not and at which point, i.e. at which distance, the objects are present. The objects 8 can furthermore be measured or a surrounding contour and its change can be detected. The monitored zone is monitored within a fan- like plane by the fan-like transmission of the light beams or by the fan-like reception. The transmission elements 5 or reception elements 6 are arranged, for example, radially symmetrically in the periphery of a cylinder The laser scanner 2 can be produced with high angular precision since the transmission elements 5 and reception elements 6 are firmly fixed and the light beams 11 enter into the monitored zone directly without moving parts. The angular precision of the angular directions can be checked and set in the production of the laser scanner 2. It is thereby ensured that every laser scanner 2 observes a specific required minimum angular precision.

For example, the laser scanner 2 in an alternative embodiment has at least one transmission element 5 and at least one reception element 6 and a control and evaluation unit 7 for evaluating the time of flight of light beams 11 from the transmission element 5 via an object 8 to the reception element 6. In this respect, a deflection unit is provided to deflect the transmitted light beams of the transmission element 5 and/or to deflect the received light beams for the reception element 6. The transmission element 5 has the laser diode LD.

Due to the deflection unit, only a single transmission element 5 and/or a single reception element 6 has to be provided.

For example, the laser scanner is a multiplane laser scanner, wherein the multiplane laser scanner is configured to form a plurality of scan planes. The plurality of scan planes can, for example, be arranged in fan shape. However, provision can also be made to form a plurality of parallel scan planes.

### REFERENCE NUMERALS

1 electronic circuit
2 laser scanner
3 input contact
4 control signal input
5 transmission element
6 reception element
7 control and evaluation unit
8 object
9 housing
11 light beams
12 laser trigger signal
13 lenses
C1 first capacitor
L1 coil
D1 first diode
Q1 switch element
LD laser diode
D2 second diode
C2 second capacitor
FET-Q1 field effect transistor
GaN-Q1 gallium nitride field effect transistor

1. An electronic circuit for generating laser pulses for a laser scanner, having an input contact for an input voltage,
having a serial connection connected to the input contact, comprising at least one coil and at least one first diode, wherein the first diode is connected in the forward direction for the input voltage,
wherein at least one switch element is arranged connected to the serial connection;
wherein a switch path is formed by means of the switch element;
wherein a laser trigger signal can be applied to the gate of the switch element;
wherein at least one antiparallel circuit of a laser diode and a second diode is connected to the cathode of the first diode and the switch element at one end;
wherein the antiparallel circuit of the laser diode and the second diode is connected to at least one first capacitor at the other end;
and the first capacitor is connected to ground with the other end; and
wherein an optical laser pulse can be generated at the laser diode by the laser trigger signal.

2. The electronic circuit in accordance with claim 1, wherein at least one second capacitor connected in parallel is arranged connected to the input contact.

3. The electronic circuit in accordance with claim 1, wherein the switch element is a switch transistor.

4. The electronic circuit in accordance with claim 3, wherein the a switch transistor is a field effect transistor.

5. The electronic circuit in accordance with claim 4, wherein the field effect transistor is a gallium nitride field effect transistor.

6. The electronic circuit in accordance with claim 1, wherein the laser trigger signal is generated by a low-side driver.

7. The electronic circuit in accordance with claim 2, wherein the capacitance of the second capacitor is at least 500 times greater than the capacitance of the first capacitor.

8. The electronic circuit in accordance with claim 7, wherein the capacitance of the second capacitor is at least 1000 times greater than the capacitance of the first capacitor.

9. The electronic circuit in accordance with claim 1, wherein the switch element is closed by the laser trigger signal for only up to 50 nanoseconds to release a laser pulse at the laser diode.

10. The electronic circuit in accordance with claim 9, wherein the switch element is closed by the laser trigger signal for 15 to 20 nanoseconds to release a laser pulse at the laser diode.

11. The electronic circuit in accordance with claim 1, wherein the energy per laser pulse is set by a control of the input supply voltage.

12. The electronic circuit in accordance with claim 1, wherein the energy per laser pulse is not set by a change of the pulse width of the laser trigger signal.

13. The electronic circuit in accordance with claim 1, wherein the first capacitor, the laser diode, and the switch element form a resonant discharge driver.

14. The electronic circuit in accordance with claim 1, wherein the inductor, the first diode, and the switch element form a boost converter circuit,
wherein the switch element is only closed for a limited time so that a voltage is produced due to the circuit that is only in dependence on the input voltage, is thus deterministic, and practically corresponds to twice the input voltage.

15. The electronic circuit in accordance with claim 1, wherein further antiparallel circuits of laser diodes are connected in parallel with the antiparallel circuit of the laser diode and the second diode, with said further antiparallel circuits each being connected to at least one further capacitor;
and these being connected to ground at the other end, with an optical laser pulse being able to be generated simultaneously at all the laser diodes by the laser trigger signal at the switch element.

16. The electronic circuit in accordance with claim 13,
wherein the laser diodes are arranged in a common housing or on a common substrate.

17. A laser scanner having at least one transmission element and at least one reception element and a control and evaluation unit for evaluating the time of flight of light beams from the transmission element via an object to the reception element with an electronic circuit, the electronic circuit having an input contact for an input voltage,
having a serial connection connected to the input contact, comprising at least one coil and at least one first diode, wherein the first diode is connected in the forward direction for the input voltage,
wherein at least one switch element is arranged connected to the serial connection;
wherein a switch path is formed by means of the switch element;
wherein a laser trigger signal can be applied to the gate of the switch element;
wherein at least one antiparallel circuit of a laser diode and a second diode is connected to the cathode of the first diode and the switch element at one end;
wherein the antiparallel circuit of the laser diode and the second diode is connected to at least one first capacitor at the other end;
and the first capacitor is connected to ground with the other end; and
wherein an optical laser pulse can be generated at the laser diode by the laser trigger signal.

18. The laser scanner in accordance with claim 17,
wherein a plurality of transmission elements and a plurality of reception elements are arranged in a common housing, wherein the light beams are transmitted and/or received in different angular directions in fan shape, wherein the spacings of the transmitted light beams of the transmission elements increase as the distance from the laser scanner increases and/or the spacings of the received light beams of the reception elements decrease as the distance from the laser scanner decreases.

19. The laser scanner in accordance with claim 17,
wherein a deflection unit is provided to deflect the transmitted light beams of the transmission element and/or to deflect the received light beams for the reception element.

20. The laser scanner in accordance with claim 17,
wherein the laser scanner is a multiplane laser scanner, with the multiplane laser scanner being configured to form a plurality of scan planes.
